(19) United States
(12) Patent Application Publication
(10) Pub. No.: US 2024/0130117 A1
(43) Pub. Date: Apr. 18, 2024

(54) METHODS FOR FORMING DRAM DEVICES WITHOUT TRENCH FILL VOIDS

(71) Applicant: Applied Materials, Inc., Santa Clara, CA (US)

(72) Inventors: Sipeng GU, Clifton Park, NY (US); Liang HONG, Hefei (CN); Jun-Feng LU, Pudong new area (CN)

(73) Assignee: Applied Materials, Inc., Santa Clara, CA (US)

(21) Appl. No.: 18/481,163

(22) Filed: Oct. 4, 2023

Related U.S. Application Data
(63) Continuation of application No. PCT/CN2022/124946, filed on Oct. 12, 2022.

(51) Int. Cl. H10B 12/00

(52) U.S. Cl. CPC H10B 12/485; H10B 12/02

(57) ABSTRACT

Disclosed herein are approaches for forming dynamic DRAM devices without trench fill voids. A method may include providing a plurality of trenches in a substrate, the plurality of trenches defining a plurality of device structures, and depositing a plurality of layers over the device structures. The layers may include a first layer over the device structures, a second layer over the first layer, and a third layer over the second layer. The method may further include forming a plurality of contact trenches through the plurality of layers to expose one or more device structures of the plurality of device structures, and directing ions into a sidewall of the trenches at a non-zero angle, wherein the ions impact the third layer without impacting the second layer. The method may further include forming a fill material within the trenches after the ions are directed into the sidewall of the trenches.

### CROSS-REFERENCE TO RELATED APPLICATIONS

This application is a continuation and claims the benefit of priority of International Application No. PCT/US2017/064269, filed Oct. 12, 2022, entirety of which is incorporated herein by reference.

### FIELD OF THE DISCLOSURE

The present disclosure relates to semiconductor structures and, more particularly, to methods for forming dynamic random-access memory (DRAM) devices without trench fill voids.

### BACKGROUND OF THE DISCLOSURE

Presently, the density of dynamic random-access memory (DRAM) increases continuously. It is thus necessary to scaling the bit-line node contact (BLC) used in cell transistor for high-density DRAM device. This portion affects the electrical resistance of cell transistor, thus the cell performance such as the write recovery time and refresh time. Typically, the BLC plug is a n⁺-doped polysilicon filled in the trench to serve as an electrode plate for the capacitor. However, seams or voids often remain within the trench following the polysilicon fill process, which contributes to increased resistance and decreased reliability and DRAM scaling. In some prior art techniques, a series of deposition and etch steps are used in an effort to address this problem. However, this results in increased device damage, particle concerns, and difficulty with continued scaling with smaller features.

It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a plurality of trenches in a substrate, the plurality of trenches defining a plurality of device structures, and depositing a plurality of layers over the plurality of device structures. The plurality of layers may include a first layer over the plurality of device structures, a second layer over the first layer, and a third layer over the second layer. The method may further include forming a plurality of contact trenches through the plurality of layers to expose one or more device structures of the plurality of device structures, directing ions into a sidewall of the plurality of contact trenches at a non-zero angle relative to a perpendicular extending from a top surface of the plurality of layers, wherein the ions impact the third layer without impacting the second layer, and forming a fill material within the plurality of contact trenches after the ions are directed into the sidewall of the plurality of contact trenches.

In another aspect, a method of forming a DRAM device may include forming a source-trench-isolation (STI) material over a plurality of trenches in a substrate, the plurality of trenches defining a plurality of device structures. The method may further include depositing a plurality of layers over the plurality of device structures, the plurality of layers comprising a first layer over the STI material, a second layer atop the first layer, and a third layer atop the second layer, wherein the second layer and the third layer are different materials. The method may further include forming a plurality of contact trenches through the plurality of layers to expose one or more device structures of the plurality of device structures, directing ions into a sidewall of the plurality of contact trenches at a non-zero angle relative to a perpendicular extending from a top surface of the plurality of layers, wherein the ions impact the third layer without impacting the second layer, and forming a fill material within the plurality of contact trenches after the ions are directed into the sidewall of the plurality of contact trenches.

In yet another aspect, a method of forming bit line contacts of a DRAM device may include providing a plurality of trenches in a substrate, the plurality of trenches defining a plurality of device structures, and depositing a plurality of layers over the plurality of device structures, wherein the plurality of layers include a first layer atop the plurality of device structures, a second layer atop the first layer, and a third layer atop the second layer, and wherein the second layer and the third layer are different materials. The method may further include forming a plurality of contact trenches through the plurality of layers to expose one or more device structures of the plurality of device structures, forming a passivation layer along a sidewall of the plurality of trenches by directing ions into the sidewall of the plurality of contact trenches at a non-zero angle relative to a perpendicular extending from a top surface of the plurality of layers, wherein the ions impact the third layer without impacting the second layer, and forming a fill material within the plurality of contact trenches after the ions are directed into the sidewall of the plurality of contact trenches.

### BRIEF DESCRIPTION OF THE DRAWINGS

The accompanying drawings illustrate exemplary approaches of the disclosure, including the practical application of the principles thereof, as follows:

FIG. 1 is a cross-sectional side view of a device including a plurality of layers over a plurality of trenches and over a plurality of device structures, according to embodiments of the present disclosure;

FIG. 2 is a side cross-sectional view illustrating the device following formation of a plurality of contact trenches, according to embodiments of the present disclosure;

FIG. 3 is a side cross-sectional view illustrating the device during an angled ion implant, according to embodiments of the present disclosure;

FIGS. 4-5 are side cross-sectional views illustrating the device during formation of a trench fill material, according to embodiments of the present disclosure; and

FIG. 6 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously use an angled ion implantation to modify desired portions of trench surfaces of a DRAM plug, which normalizes growth rates of a subsequently formed trench fill. In doing so, voids or gaps within the trench fill are avoided. As a result, resistance is decreased, while reliability and DRAM scaling are increased.

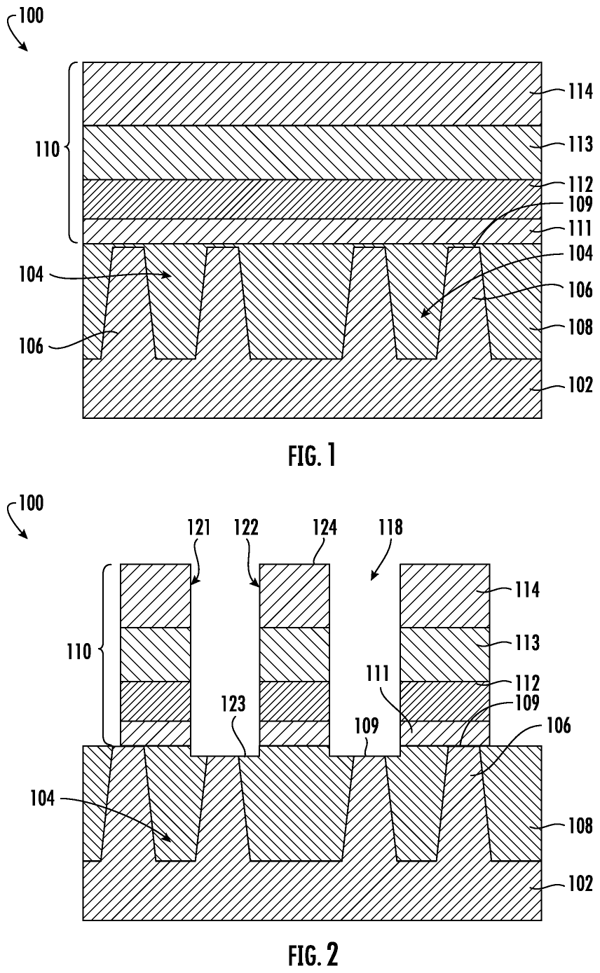

FIG. 1 is a side cross-sectional view of a portion of semiconductor device (hereinafter “device”) 100, such as a DRAM device, according to one or more embodiments. As shown, the device 100 may include a base or substrate 102 including a plurality of trenches 104 and a plurality of device structures 106. Although non-limiting, the plurality of device structures 106 may correspond to a plurality of source-trench-isolation (STI) structures. An STI fill material 108 may be formed over the device structures 106 and within the trenches 104. The STI fill material 108 may be planarized to an upper surface 109 of the device structures 106.

As further shown, a plurality of layers 110 may be formed over the STI fill material 108 and over the device structures 106. In some embodiments, a first layer 111 may be formed over the STI fill material 108, a second layer 112 may be formed over the first layer 111, a third layer 113 may be formed over the second layer 112, and a fourth layer 114 may be formed over the third layer 113. The third layer 113 and the second layer 112 may be different materials, while the first layer 111 and the fourth layer 114 may be the same material. In this non-limiting example, the first layer 111 is an oxide material, the second layer 112 is a silicon nitride layer, the third layer 113 is a polysilicon layer, and the fourth layer 114 is an oxide material. It will be appreciated that a lesser or greater number of layers may be present in the plurality of layers 110. It will be further appreciated that the materials for each of the plurality of layers 110 may vary in alternative embodiments.

As shown in FIG. 2, a plurality of contact trenches 118 may then be formed (e.g., etched) through the plurality of layers 110 to expose one or more of the device structures 106. In some embodiments, the etch process may recess the upper surface 109 of one or more of the device structures 106 and the STI fill material 108. Each of the plurality of contact trenches 118 is defined by a first sidewall 121 and a second sidewall 122 extending between a trench bottom 123 and an upper surface 124 of the plurality of layers 110. Within each of the plurality of contact trenches 118 is an exposed portion of the first layer 111, the second layer 112, the third layer 113, and the fourth layer 114.

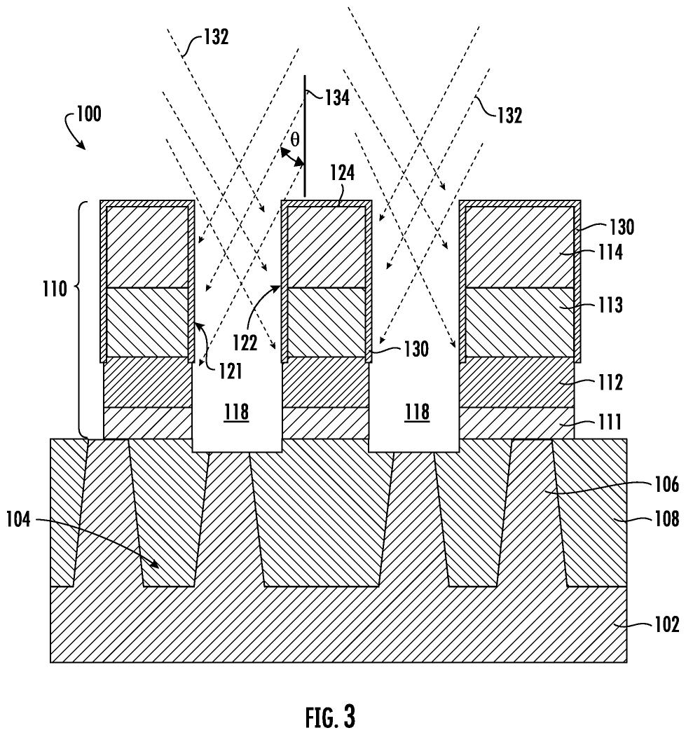

As shown in FIG. 3, portions of the first and second sidewalls 121, 122 of each of the plurality of contact trenches 118 may then be passivated by ions 132 directed/delivered into the plurality of contact trenches 118 at a non-zero angle ‘θ’ relative to a perpendicular 134 extending from the upper surface 124 of the plurality of layers 110. Said another way, a passivation layer 130 may be formed over the plurality of layers 110, including along an upper portion of the first and second sidewalls 121, 122 of each of the plurality of contact trenches 118. In exemplary embodiments, the ions 132 may impact the third layer 113 and the fourth layer 114 without impacting the second layer 112 or the first layer 111. As a result, the passivation layer 130 may be formed over the third and fourth layers 113, 114 without being formed over the first or second layers 111, 112. In some embodiments, the passivation layer 130 will be formed along the second layer 112 and the first layer 111, in addition to along the third layer 113 and the fourth layer 114, but not along on the trench bottom 123. In some embodiments, the passivation layer 130 may be formed partially along the second layer 112 within the plurality of contact trenches 118.

In various embodiments, the ions 132 may be oxygen and/or nitrogen ions delivered at an angle of approximately 25-65°. One will appreciate the implantation angle may vary in other embodiments by +/−10°, for example. The ions may be implanted into the plurality of contact trenches 118 at an angle selected to prevent ions from impacting the second layer 112, the first layer 111, and the trench bottom 123.

It will be appreciated that the degree to which the physical and/or chemical composition of the first and second sidewalls 121, 122 of each of the plurality of contact trenches 118 is modified may be determined by one or more variables, including, but not limited to, the species of ion selected, the material properties of the surfaces being modified, the rotational orientation of the device 100, the temperature at which the ions are implanted, the concentration and/or dosage of the ions being implanted, and the amount of energy with which the ions are implanted into the surfaces being modified. Furthermore, the device 100 may be rotated during or between successive implants so each of the first and second sidewalls 121, 122 of the device 100 is impacted. For example, the device 100 may be rotated between each implant process by 45°, 90°, 180°, etc. Embodiments herein are not limited in this context.

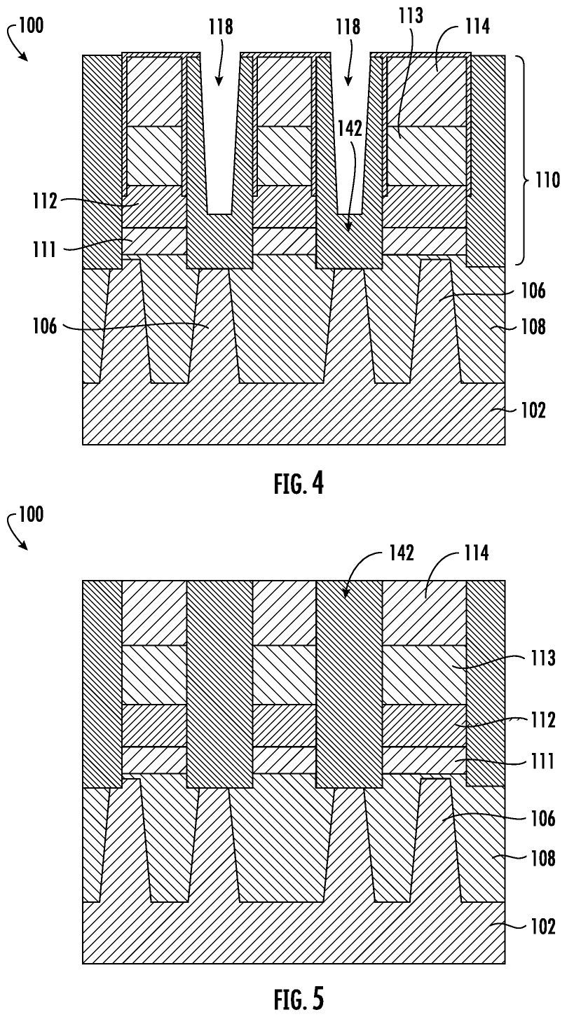

As shown in FIG. 4, a fill material 142 may then be formed within the plurality of contact trenches 118 following formation of the passivation layer 130. More specifically, polysilicon may be epitaxially grown within each of the plurality of contact trenches 118, including over each of the first layer 111, the second layer 112, the third layer 113, and the fourth layer 114. As shown, the fill material 142 may be in direct contact with one or more of the device structures 106. In general, Si growth rate is higher on Si surfaces than on SiN surfaces, resulting in pinch off in the middle portion with poly, which generates a gap or void inside the poly fill material. However, in the present disclosure, due to the surface modification from the ions 132 along the upper portions of the plurality of contact trenches 118 (e.g., along the third and fourth layers 113, 114), a growth rate of the fill material 142 along the third layer 113 is delayed or retarded. As a result, the fill material 142 generally grows at a same or similar rate along both the second and third layers 112, 113 of the plurality of layers 110. As shown in FIG. 5, once the fill material 142 entirely fills the plurality of contact trenches 118 (and is subsequently planarized), no voids or seams are present within the fill material 142.

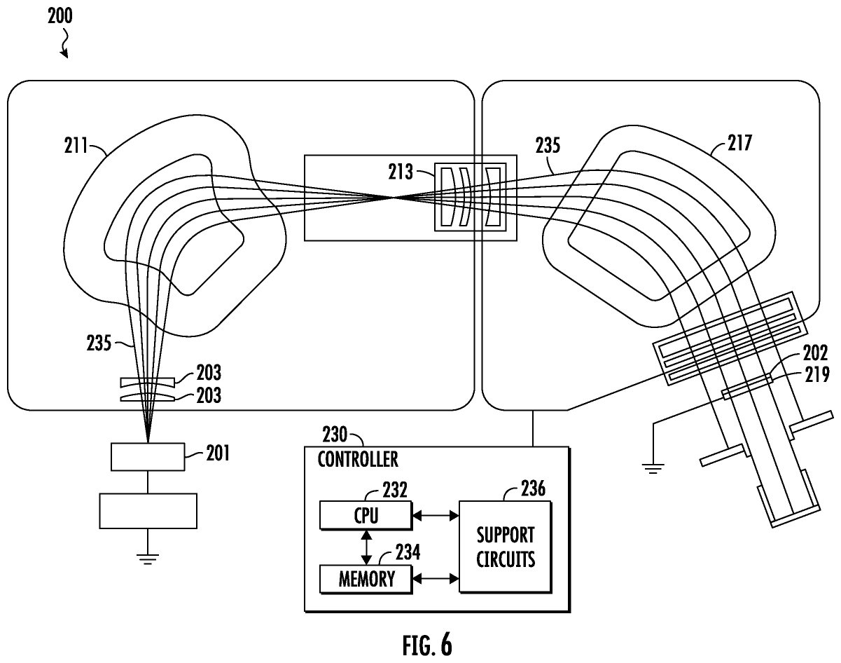

FIG. 6 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the implant of ions 132 demonstrated in FIG. 3. The ion source 201 may also provide an ion etch, such as the etch used to form the plurality of contact trenches 118.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the substrate 102 described above. The substrate 202 may be moved in one or more dimensions (e.g., translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the device 100, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a plurality of trenches in a substrate, the plurality of trenches defining a plurality of device structures;
depositing a plurality of layers over the plurality of device structures, the plurality of layers comprising a first layer over the plurality of device structures, a second layer over the first layer, and a third layer over the second layer;
forming a plurality of contact trenches through the plurality of layers to expose one or more device structures of the plurality of device structures;
directing ions into a sidewall of the plurality of contact trenches at a non-zero angle relative to a perpendicular extending from a top surface of the plurality of layers, wherein the ions impact the third layer without impacting the second layer; and
forming a fill material within the plurality of contact trenches after the ions are directed into the sidewall of the plurality of contact trenches.

2. The method of claim 1, further comprising:
forming the fill material beyond the top surface of the plurality of layers; and
planarizing the fill material.

3. The method of claim 1, further comprising forming a fourth layer over the third layer of the plurality of layers, wherein the fourth layer and the first layer are a same material.

4. The method of claim 3, further comprising directing ions into the sidewall of the plurality of contact trenches to form a passivation layer along the sidewall of the plurality of contact trenches, wherein the passivation layer is formed over the fourth layer and the third layer without being formed over the second layer or the first layer, and wherein the passivation layer retards growth of the fill material along the third layer.

5. The method of claim 3, wherein the first layer is an oxide material, wherein the second layer is a silicon nitride layer, wherein the third layer is a polysilicon layer, and wherein the fourth layer is the oxide material.

6. The method of claim 1, wherein the fill material is formed directly atop the one or more device structures of the plurality of device structures.

7. The method of claim 1, wherein forming the fill material within the plurality of contact trenches comprises epitaxially growing a polysilicon within the plurality of contact trenches.

8. A method of forming a DRAM device, the method comprising:
forming a source-trench-isolation (STI) material over a plurality of trenches in a substrate, the plurality of trenches defining a plurality of device structures;
depositing a plurality of layers over the plurality of device structures, the plurality of layers comprising a first layer over the STI material, a second layer atop the first layer, and a third layer atop the second layer, wherein the second layer and the third layer are different materials;
forming a plurality of contact trenches through the plurality of layers to expose one or more device structures of the plurality of device structures;
directing ions into a sidewall of the plurality of contact trenches at a non-zero angle relative to a perpendicular extending from a top surface of the plurality of layers, wherein the ions impact the third layer without impacting the second layer; and
forming a fill material within the plurality of contact trenches after the ions are directed into the sidewall of the plurality of contact trenches.

9. The method of claim 8, further comprising:
forming the fill material over the top surface of the plurality of layers; and
planarizing the fill material to the top surface of the plurality of layers.

10. The method of claim 8, further comprising forming a fourth layer over the third layer of the plurality of layers, wherein the fourth layer and the first layer are a same material.

11. The method of claim 10, wherein directing ions into the sidewall of the plurality of contact trenches results in a passivation layer being formed along the sidewall of the plurality of trenches, wherein the passivation layer is formed over the fourth layer and the third layer without being formed over the second or third layer, and wherein the passivation layer retards growth of the fill material along the third layer.

12. The method of claim 10, wherein the first layer is an oxide material, wherein the second layer is a silicon nitride layer, wherein the third layer is a polysilicon layer, and wherein the fourth layer is the oxide material.

13. The method of claim 8, wherein the fill material is formed directly atop the one or more device structures of the plurality of device structures.

14. The method of claim 8, wherein forming the fill material within the plurality of contact trenches comprises epitaxially growing a polysilicon within the plurality of contact trenches.

15. A method of forming bit line contacts of a DRAM device, the method comprising:
providing a plurality of trenches in a substrate, the plurality of trenches defining a plurality of device structures;
depositing a plurality of layers over the plurality of device structures, the plurality of layers comprising a first layer atop the plurality of device structures, a second layer atop the first layer, and a third layer atop the second layer, wherein the second layer and the third layer are different materials;
forming a plurality of contact trenches through the plurality of layers to expose one or more device structures of the plurality of device structures;
forming a passivation layer along a sidewall of the plurality of contact trenches by directing ions into the sidewall of the plurality of contact trenches at a non-zero angle relative to a perpendicular extending from a top surface of the plurality of layers, wherein the ions impact the third layer without impacting the second layer; and
forming a fill material within the plurality of contact trenches after the ions are directed into the sidewall of the plurality of contact trenches.

16. The method of claim 15, further comprising forming a fourth layer over the third layer of the plurality of layers, wherein the fourth layer and the first layer are a same material.

17. The method of claim 16, wherein the passivation layer is formed over only the fourth layer and the third layer, and wherein the passivation layer retards growth of the fill material along the third layer.

18. The method of claim 16, wherein the first layer is an oxide material, wherein the second layer is a silicon nitride layer, wherein the third layer is a polysilicon layer, and wherein the fourth layer is the oxide material.

19. The method of claim 15, wherein the fill material is formed directly atop the one or more device structures of the plurality of device structures.

20. The method of claim 15, wherein forming the fill material within the plurality of contact trenches comprises epitaxially growing a polysilicon within the plurality of contact trenches, and wherein retarding epitaxial growth of the polysilicon along the third layer relative to along the second layer prevents formation of a void within the fill material after the fill material reach the top surface of the plurality of layers.
